(19) United States
(12) Patent Application Publication
(10) Pub. No.: US 2022/0051918 A1
(43) Pub. Date: Feb. 17, 2022

(54) TRANSFER CHAMBER WITH INTEGRATED SUBSTRATE PRE-PROCESS CHAMBER

(71) Applicant: Applied Materials, Inc., Santa Clara, CA (US)

(72) Inventors: Kirankumar Neelasandra SAVANDAIAH, Bangalore (IN); Lakshmikanth Krishnamurthy SHIRAHATTI, Bangalore (IN); Srinivasa Rao YEDLA, Bangalore (IN); Thomas BREZOCZKY, Los Gatos, CA (US)

(21) Appl. No.: 16/992,894

(22) Filed: Aug. 13, 2020

(51) Int. Cl. H01L 21/67; C23C 14/50

(52) U.S. Cl. CPC H01L 21/67196; H01L 21/67126; H01L 21/68707; C23C 14/50; H01L 21/67167

(57) ABSTRACT

A transfer chamber includes a monolithic chamber body, a transfer robot configured to pass substrates between a factory interface and a processing module in a substrate processing system, a load lock chamber station, a shutter station, a pre-clean chamber station, and a process chamber station integrated within the monolithic chamber body, and a plurality of slit valves integrated within the monolithic chamber body. The plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

### BACKGROUND

### Field

Embodiments of the present disclosure generally relate to an apparatus and method of processing substrates in a sub-atmospheric pressure environment, and more particularly, an integrated monolith buffer station for pre-processing substrates.

### Description of the Related Art

Conventional cluster tools are configured to perform one or more processes during substrate processing. For example, a cluster tool can include a physical vapor deposition (PVD) chamber, an atomic layer deposition (ALD) chamber, a chemical vapor deposition (CVD) chamber, and/or one or more other processing chambers for performing one or more other processes on a substrate. Many thin film deposition and etch processes employ pre-processes such as cleaning, de-gassing, cooling-down, and annealing in dedicated chambers that are attached to a cluster tool, prior to processing in a processing chamber. The time required to load and unload a substrate from one chamber to another using a robot and pump down each chamber adds overhead time to the total time required to process a substrate in a cluster tool, decreases throughput, and increases cost of ownership (CoO).

Therefore, there is the need in the art for methods and apparatus for performing pre-processing of substrates that increases mechanical throughput and decreases CoO.

### SUMMARY

Embodiments described herein provide a transfer chamber in a substrate processing system. The transfer chamber includes a monolithic chamber body, a transfer robot configured to pass substrates between a factory interface and a processing module in a substrate processing system, a load lock chamber station, a shutter station, a pre-clean chamber station, and a process chamber station integrated within the monolithic chamber body, and a plurality of slit valves integrated within the monolithic chamber body. The plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

Embodiments described herein provide a substrate processing system. A substrate processing system includes a processing module comprising one or more processing chambers, a factory interface comprising one or more front opening unified pods, a transfer chamber coupled between the factory interface and the processing module. The transfer chamber includes a monolithic chamber body, a transfer robot configured to pass substrates between a factory interface and a processing module in a substrate processing system, a load lock chamber station, a shutter station, a pre-clean chamber station, and a process chamber station integrated within the monolithic chamber body, and a plurality of slit valves integrated within the monolithic chamber body. The plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic view of a processing system according to one embodiment.

FIG. 2 is a schematic view of a transfer chamber according to one embodiment.

FIG. 3 is a plan view of a transfer robot according to one embodiment

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide a transfer chamber (also referred to as a “buffer station”) attached to a main frame in a substrate processing system. The transfer chamber includes load lock chamber stations, pre-clean/degas chamber station, and an optional process chamber station integrated in a monolithic chamber body, in which pre-processes such as cleaning, de-gassing, cooling-down, and annealing can be performed. The necessity to load and unload a substrate from one chamber to another using a robot and pump down each chamber for such pre-processes in a conventional cluster tool is removed, and thus the total time required to process a substrate in the substrate processing system is decreased, leading to an increased throughput. The transfer chamber further includes a plurality of slit valves integrated within the monolithic chamber body. The plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

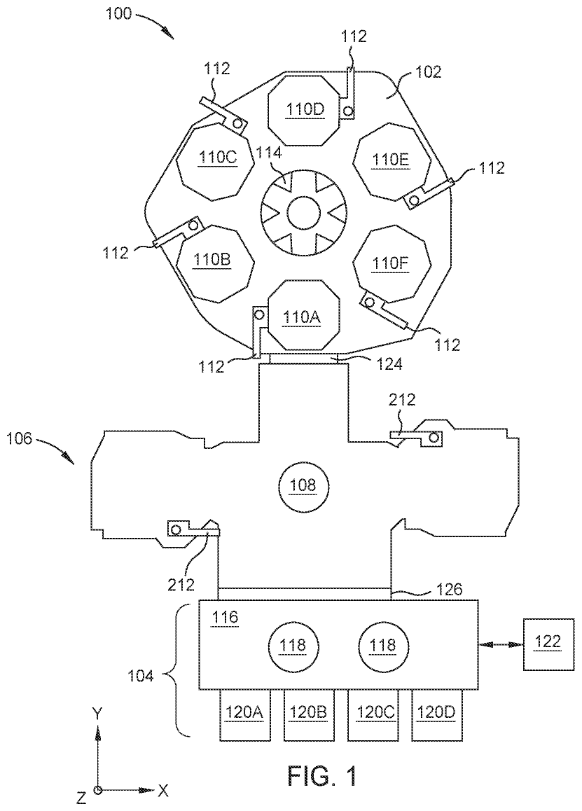

FIG. 1 is a schematic view of a processing system 100 according to one embodiment. The processing system 100 generally includes a processing module 102, a factory interface 104, a transfer chamber (also referred to as a “buffer station”) 106 that is coupled between the processing module 102 and the factory interface 104, and a system controller 122. The transfer chamber 106 is configured to pass substrates from the factory interface 104 into the processing module 102, as well as from the processing module 102 into the factory interface 104 by a transfer robot 108 associated with the transfer chamber 106.

In the example shown in FIG. 1, the processing module 102 includes six accessible process stations 110A-110F (collectively labelled as 110) and the process station 110A is connected to the transfer chamber 106 through a process chamber valve 124. Each processing station 110 is coupled to a vacuum pump 112 that is configured to evacuate a processing region of the processing station 110. A substrate may be sequentially moved from one process station 110 to another process station 110 within the processing module 102. Each process station 110 may be independently or similarly configured to enable one or more deposition processes, such as physical vapor deposition (PVD), chemical vapor deposition (CVD), plasma-enhanced chemical vapor deposition (PECVD), atomic layer deposition (ALD), and plasma-enhanced atomic layer deposition (PEALD), etching process, thermal process (e.g., rapid thermal processing (RTP), annealing, cooling down, thermal management control). A central transfer robot 114 is configured to transfer a substrate from one processing station 110 to another processing station 110. A substrate loaded into the processing module 102 need not be processed at each process station 110A-110F. For example, all six process stations 110 may employ the same sputter target material, six substrates are loaded into the processing module 102, and each substrate is processed in a different one of the process stations 110 for deposition of a same material film layer thereon. Thereafter all six substrates are removed from the processing module 102, and another set of six substrates are loaded into the processing module 102, and the processing of each substrate in each process station 110 is performed. Alternatively, different processes are performed in different process stations 110 within the processing module 102. For example, a first deposition process to deposit a first type of film layer is performed in process stations 110A, 110C and 110E, and a second deposition process to deposit a second type of film layer is performed in process stations 110A, 110C and 110E. In this case, an individual substrate is exposed to only two process stations 110, for example a first substrate is exposed to only process stations 110A and 1108, a second substrate is exposed to only process stations 110C and 110D, and a third substrate is exposed to only process stations 110E and 110F. Then the substrates are removed. Likewise, each substrate process in the processing system 100 can be processed in up to all process stations 110, and the process performed at each process station 110 can be the same or different from one or all of the remaining process stations 110. While the example provided herein generally illustrates a processing module that includes six process stations, this configuration is not intended to be limiting as to the scope of the invention provided herein, since a processing module 102 might alternatively include two or more process stations 110, such as four or more process stations 110, eight or more process stations 110, ten or more process stations 110, or even 12 or more process stations 110.

The factory interface 104 is connected to the transfer chamber 106 through a load lock chamber valve 126 at one side thereof to the factory interface 104. The factory interface 104 is an atmospheric or ambient pressure substrate input and output handling station in which substrates are safely secured and stored as the substrates are moved between different machines. In some embodiments, the factory interface 104 may be maintained in a positive-pressure non-reactive gas environment (using, e.g., nitrogen as the non-reactive gas) with minimum 4 torr above atmospheric pressure using a purging apparatus (e.g., a gas supply line, a gas source, a vacuum pump, a valve, or the like, not shown) located within and/or coupled to the processing system 100. This non-reactive gas environment prevents substrates from exposure to air, in particular oxygen, and moisture, which may adversely affect substrate properties and substrate processing due to oxidation.

In some embodiments, the factory interface 104 includes at least one docking station 116 and at least one factory interface robot 118 to facilitate the transfer of a substrate. The docking station 116 is configured to accept one or more front opening unified pod (FOUP). Four FOUPs, such as 120A, 120B, 120C, and 120D (collectively labeled as 120) are shown in the embodiment of FIG. 1. The factory interface robot 118 is configured to transfer a substrate from the factory interface 104 to the transfer chamber 106.

The system controller 122 controls activities and operating parameters of the automated components found in the processing system 100. In general, the bulk of the movement of a substrate through the processing system is performed using the various automated devices disclosed herein by use of commands sent by the system controller 122. The system controller 122 is a general use computer that is used to control one or more components found in the processing system 100. The system controller 122 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, and/or positioning of a substrate along with the various process recipe tasks and various processing module process recipe steps being performed.

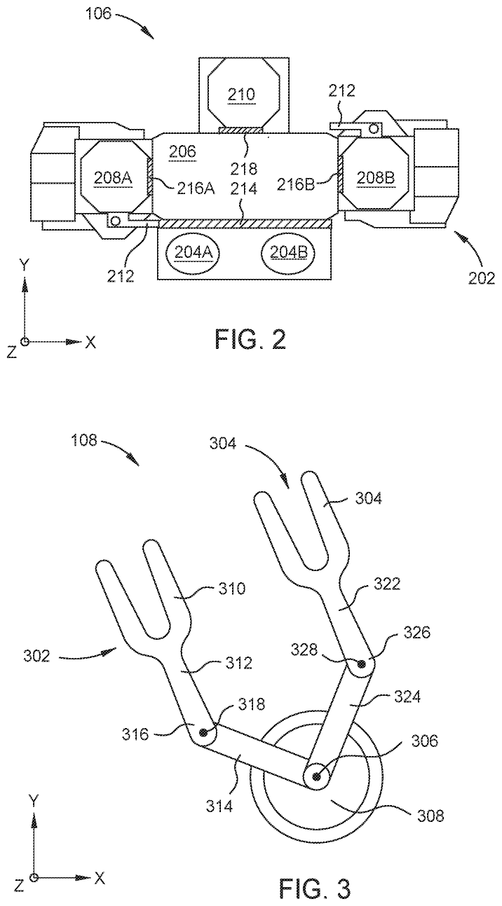

FIG. 2 is a schematic view of the transfer chamber 106 according to one embodiment. The transfer chamber 106 is formed of a monolithic chamber body 202 having a pair of load lock chamber stations 204A, 204B, a shutter station 206, preclean/degas chamber stations 208A, 208B, and an optional process chamber station 210 integrated within the chamber body 202. The monolithic chamber body 202 is formed of an aluminum material (e.g., 6061 Al).

The load lock chamber stations 204A, 204B are connected through the load lock chamber valve 126 (shown in FIG. 1). The process chamber station 210 is connected to the process station 110A of the processing module 102 through the process chamber valve 124 (shown in FIG. 1). A substrate is passed from the factory interface 104 into the process station 110A of the processing module 102 as well as from the process station 110A of the processing module 102 into the factory interface 104 through the transfer chamber 106 by the transfer robot 108. For example, to pass a substrate from the process station 110A of the processing module 102 to the factory interface 104, the process chamber valve 124 is opened and an end effector of the transfer robot 108 retracts the substrate from the process station 110A of the processing module 102. The end effector of the transfer robot 108 is then retracted from the process station 110A of the processing module 102 back inside the transfer chamber 106 and the process chamber valve 124 is closed. Subsequently, the load lock chamber valve 126 is opened and the end effector of the transfer robot 108 transfers the substrate from the transfer chamber 106 to the factory interface 104. Once the substrate is positioned in the factory interface 104, the end effecter of the transfer robot 108 is retracted from the factory interface 104 back inside the transfer chamber 106 and the load lock chamber valve 126 is closed.

The interior volume of the transfer chamber 106 is evacuated by one or more vacuum pumps 212 connected to an exhaust duct (not shown) of the transfer chamber 106 to reduce the pressure within the transfer chamber 106 to a sub-atmospheric pressure of between about 10⁻⁵ torr and about 10⁻⁸ torr, for example, about 10⁻⁷ torr. The vacuum pumps 212 may be a turbopump, cryopump, roughing pump or other useful device that is able to maintain a desired pressure within the interior volume of the transfer chamber 106. When the load lock chamber valve 126 is open, the interior of the transfer chamber 106 is exposed to atmospheric or ambient pressure conditions.

The transfer chamber 106 includes integrated slit valves 214, 216A, 216B, 218 to control the load lock chamber stations 204A, 204B, the preclean/degas chamber stations 208A, 208B, and the process chamber station 210 at different vacuum pressures for use of various different processing gases without the concern of contaminating among different stations within the transfer chamber 106. In one example, the process chamber station 210 is maintained at a pressure of between about 10⁻⁴ torr and about 10⁻⁸ torr, for example, 10⁻⁵ torr. The integrated slit valve 214 is configured to close the load lock chamber stations 204A, 204B, from the shutter station 206. The integrated slit valve 216A, 216B are configured to close the preclean/degas chamber stations 208A, 208B, respectively, from the shutter station 206. The integrated slit valve 218 is configured to close the process chamber station 210 from the shutter station 206. In some embodiments, the transfer chamber 106 includes a wafer station (not shown) located therewithin to accommodate a wafer that is either to be pre-processed or has been pre-processed and ready to be passed to process chamber station 210.

During operation, a substrate transferred from the factory interface 104 into one of the load lock chamber stations 204A, 204B may be moved to one of the preclean/degas chamber stations 208A, 208B or the process chamber station 210 through the shutter station 206 within the transfer chamber 106 by the transfer robot 108. Alternatively, a substrate processed within the processing module 102 and transferred into the process chamber station 210 of the transfer chamber 106 may be moved back to one of the load lock chamber stations 204A, 204B through the shutter station 206 within the transfer chamber 106 and subsequently out to the factory interface 104.

In the preclean/degas chamber stations 208A, 208B, a substrate is pre-cleaned prior to being transferred into the processing module 102 for substrate processing. The pre-cleaning process may include heating the substrate to volatilize any adsorbed moisture or other volatilizable materials therefrom. The pre-cleaning process may be subjecting the substrate to a plasma etch process whereby residual contaminant materials thereon are removed. In some embodiments, the preclean/degas chamber stations 208A, 208B pre-clean two substrates simultaneously. For example, one substrate is transferred from the load lock chamber station 204A to the preclean/degas chamber 208A and another substrate is transferred from the load lock chamber station 204B to the preclean/degas 208B, and the both substrates are pre-cleaned independently and simultaneously in their respective preclean/degas chambers 208A, 208B. Because the preclean/degas chambers 208A, 208B are isolated from the shutter station 206 by the integrated slit valves 216A, 216B, respectively, passages of different substrates can be undertaken from the factory interface 104 to the processing module 102 without interfering with the pre-cleaning of the substrate in the respective preclean/degas chambers 208A, 208B.

A substrate may be moved into the process chamber station 210 from the preclean/degas chamber stations 208A, 208B, for example, after the substrate has been pre-cleaned in the preclean/degas chamber stations 208A, 208B, or from the load lock chamber stations 204A, 204B, for example, when the substrate requires no pre-cleaning, through the shutter station 206 within the transfer chamber 106 by the transfer robot 108. The process chamber station 210 may be adapted to perform thermal process (e.g., rapid thermal processing (RTP), annealing, cooling down, thermal management control).

FIG. 3 depicts the transfer robot 108 that includes two end effectors 302, 304 according to one embodiment. The two end effectors 302, 304 may be independently operable. The two end effectors 302, 304 extend from and swing arcuately about a central axis 306 which extends in the Z-direction. Each end effector 302, 304 is operatively coupled to a central hub 308. The central hub 308 is generally positioned over the shutter station 206 and includes an upper rotatable hub and a lower rotatable hub (not shown) that are each independently rotatable about central axis 306. The first end effector 302 includes a first fork 310 and a first arm 312. A first hub arm 314 is coupled to the central hub 308 at a first end thereof and to the first arm 312 at the end thereof distal to the first end effector 302 at a first wrist connection 316, whereby the first arm 312 is pivotable about a first wrist axis 318 to allow the first end effector 302 to rotate about the first wrist axis 318. Likewise, the first wrist connection 316, and thus the first wrist axis 318, can orbit about the central axis 306, by virtue of the arcuate movement of the first hub arm 314 about the central axis 306. The second end effector 304 includes a second fork 320 and a second arm 322. A second hub arm 324 is coupled to the upper rotatable hub at a first end thereof and to the second arm 322 at the end thereof distal to the second end effector 304 at a second wrist connection 326, whereby second arm 322 is pivotable about a second wrist axis 328 to allow the second end effector 304 to rotate about the second wrist axis 328. Likewise, the second wrist connection 326, and thus the second wrist axis 328, can orbit about the central axis 306, by virtue of the arcuate movement of the second hub arm 324 about the central axis 306.

Each of the forks 310, 320 of the first and second end effectors 302, 304 can extend a maximum distance from the central axis 306 when the arms (first arm 312 and first hub arm 314, or second arm 322 and second hub arm 324) thereof are co-aligned, i.e., when they together form a straight line path. In this orientation of the arms, one of the first and second fork 310 or 320 is at the load or unload position to receive or leave a substrate with respect to a substrate support. From this position, by virtue of arcuate movement of an upper or lower hub about central axis 306 and one of the first or the second arms 312, 322 about the corresponding first wrist axis 318 or second wrist axis 328, the corresponding fork 310 or 320 is retracted toward the central hub 308. By locating the transfer robot 108 within the transfer chamber 106 and locating central axis 306 over the shutter station 206, the forks 310, 320 are operable to access any substrate support at any of the load lock chamber stations 204A, 204B, the preclean/degas chamber stations 208A, 208B, and the process chamber station 210, and independently of one another only through the shutter station 206.

In the example embodiments described herein, a transfer chamber attached to a main frame in a substrate processing system is shown. The transfer chamber includes load lock chamber stations, pre-clean/degas chamber station, and an optional process chamber station integrated in a monolithic chamber body, in which pre-processes such as cleaning, de-gassing, cooling-down, and annealing down can be performed. The necessity to load and unload a substrate from one chamber to another using a robot and pump down each chamber for such pre-processes in a conventional cluster tool is removed and thus the total time required to process a substrate in the substrate processing system is decreased, leading to an increased throughput. The transfer chamber further includes a plurality of slit valves integrated within the monolithic chamber body. The plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

While the foregoing is directed to various examples of the present disclosure, other and further examples may be devised without departing from the basic scope thereof, and the scope thereof is determined by the claims that follow.

What is claimed is:

1. A transfer chamber in a substrate processing system, comprising:
a monolithic chamber body;
a transfer robot configured to pass substrates between a factory interface and a processing module in a substrate processing system;
a load lock chamber station, a shutter station, a pre-clean chamber station, and a process chamber station integrated within the monolithic chamber body; and
a plurality of slit valves integrated within the monolithic chamber body, wherein the plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures.

2. The transfer chamber of claim 1, further comprising one or more pumps to evacuate an interior volume of the transfer chamber.

3. The transfer chamber of claim 2, wherein pressure within the transfer chamber is maintained between about 10⁻⁵ torr and about 10⁻⁸ torr.

4. The transfer chamber of claim 3, wherein pressure within the process chamber station is maintained between about 10⁻⁴ torr and about 10⁻⁶ torr.

5. The transfer chamber of claim 1, wherein the monolithic chamber body comprises material selected from aluminum and stainless steel.

6. The transfer chamber of claim 1, wherein the transfer robot is further configured to transfer a substrate between the load lock chamber station and the factory interface in the substrate processing system.

7. The transfer chamber of claim 1, wherein the transfer robot is further configured to transfer a substrate between the process chamber station and the factory interface in the substrate processing system.

8. The transfer chamber of claim 1, wherein the transfer robot is further configured to transfer a substrate among the load lock chamber station, the pre-clean chamber station, and the process chamber station through the shutter station.

9. A substrate processing system, comprising:
a processing module comprising one or more processing chambers;
a factory interface comprising one or more front opening unified pods;
a transfer chamber coupled between the factory interface and the processing module, the transfer chamber comprising:
a monolithic chamber body;
a load lock chamber station integrated within the monolithic chamber body and coupled to the factory interface via a load lock chamber valve;
a process chamber station integrated within the monolithic chamber body and coupled to the processing module via a process chamber valve;
a shutter station and a pre-clean chamber station integrated within the monolithic chamber body; and
a plurality of slit valves integrated within the monolithic chamber body integrated within the monolithic chamber body, wherein
the plurality of slit valves are configured to open and close the load lock chamber station, the pre-clean chamber station, and the process chamber station each from the shutter station such that the load lock chamber station, the pre-clean chamber station, and the process chamber station maintain respective vacuum pressures; and
a transfer robot configured to pass substrates between the factory interface and the process module via the transfer chamber.

10. The substrate processing system of claim 9, further comprising one or more pumps to evacuate an interior volume of the transfer chamber.

11. The substrate processing system of claim 10, wherein pressure within the transfer chamber is maintained between about 10⁻⁵ torr and about 10⁻⁸ torr.

12. The substrate processing system of claim 11, wherein pressure within the process chamber station is maintained between about 10⁻⁴ torr and about 10⁻⁸ torr.

13. The substrate processing system of claim 9, wherein the monolithic chamber body comprises material selected from aluminum and stainless steel.

14. The substrate processing system of claim 9, wherein the transfer robot is further configured to transfer a substrate between the load lock chamber station and the factory interface in the substrate processing system.

15. The substrate processing system of claim 9, wherein the transfer robot is further configured to transfer a substrate between the process chamber station and the factory interface in the substrate processing system.

16. The substrate processing system of claim 9, wherein the transfer robot is further configured to transfer a substrate among the load lock chamber station, the pre-clean chamber station, and the process chamber station through the shutter station.

17. The substrate processing system of claim 9, wherein the factory interface is maintained in a non-reactive gas environment.

18. The substrate processing system of claim 9, wherein pressure within the factory interface is maintained with minimum 4 torr above atmospheric pressure.
